(19) United States
(12) Patent Application Publication
(10) Pub. No.: US 2016/0218263 A1
(43) Pub. Date: Jul. 28, 2016

(54) PACKAGE STRUCTURE AND METHOD FOR MANUFACTURING THE SAME

(71) Applicant: Peiching Ling, Sunnyvale, CA (US)

(72) Inventors: Peiching Ling, Sunnyvale, CA (US); Dezhong Liu, Sunnyvale, CA (US)

(21) Appl. No.: 15/004,058

(22) Filed: Jan. 22, 2016

(30) Foreign Application Priority Data
Jan. 27, 2015 (TW) 104102655

(51) Int. Cl. H01L 33/62; H01L 33/50; H01L 33/00; H01L 21/683; H01L 33/44; H01L 33/64; H01L 33/54

(52) U.S. Cl. CPC H01L 33/62; H01L 33/64; H01L 33/505; H01L 33/54; H01L 21/6835; H01L 33/44; H01L 33/0095; H01L 2933/0025; H01L 2933/0066; H01L 2933/0041; H01L 2933/005; H01L 2933/0075

(57) ABSTRACT

A package structure is provided, which includes a light emitting element having opposite first and second sides, a coating body combined with side faces of the light emitting element, a fluorescent layer disposed on the second side, and a metal structure disposed on the first side. As the coating body is in contact with and combined with the side faces of the light emitting element, light will not be emitted from the side faces of the light emitting element. Therefore, the heat generated is reduced, and issues such as yellowing of the encapsulant and poor luminous efficiency due to overheating of the fluorescent powder are avoided. Further, the metal structure enhances the heat dissipation. A method for manufacturing the package structure is also provided.

### CROSS-REFERENCE TO RELATED APPLICATION

The present application is based on, and claims priority from Taiwan Application Number 104102655, filed Jan. 27, 2015, the disclosure of which is hereby incorporated by reference herein in its entirety.

### BACKGROUND

1. Technical Field

The present disclosure relates to semiconductor packages, and, more particularly, to a light emitting package.

2. Description of Related Art

With the rapid development of the electronic industry, the form factors of the electronic products are tended towards compactness and miniaturization, while their functionalities are heading in the directions of high performance, high functionalities, and high speeds. Light Emitting Diodes (LEDs) are widely used in electronic products with lighting requirements due to advantages such as their long life, small size, high shock resistance and low power consumptions. As a result, their applications are being seen in industries, various electronic products, home appliances and the like.

FIG. 1 is a cross-sectional diagram depicting a LED package 1 according to the prior art. The LED package 1 includes a substrate 10 with a reflective cup 100 formed thereon. A LED 11 is provided in the reflective cup 100, electrically connected to the substrate 10 via a plurality of conductive wires 14, and encapsulated by an encapsulant 12. A fluorescent layer 13 is formed on the encapsulant 12. A lens 15 is disposed on the fluorescent layer 15.

In the LED package 1, since the substrate 10 is required to carry the LED 11, the LED package 1 has thickness and width increased, which is contradictory to the requirement of miniaturization.

Moreover, the fluorescent layer 13 is separated too far from the LED 11, resulting in a poor luminous efficiency.

Furthermore, as the LED 11 is encapsulated in the encapsulant 13, poor heat dissipation occurs. Issues such as yellowing of the encapsulant, poor luminous efficiency due to overheating of the fluorescent powder may occur, especially for the encapsulant at a side face 11c of the LED 11.

Therefore, there is a need for a solution that addresses the aforementioned issues in the prior art.

### SUMMARY

In view of the aforementioned shortcomings of the prior art, the present disclosure provides a package structure, which may include: at least one light emitting element including opposite first and second sides and side faces adjacent to the first and second sides; a coating body in contact with and combined with the side faces of the light emitting element, wherein the coating body is made of a non-transparent material; and at least one metal structure disposed at the first side of the light emitting element.

The present disclosure further provides a method for manufacturing a package structure, which may include the following steps of: combining at least one light emitting element on a carrier, wherein the light emitting element includes a first side combined with the carrier, a second side opposite to the first side, and side faces adjacent to the first and second sides; forming on the carrier a coating body that is in contact with and combined with the side faces of the light emitting element, wherein the coating body is exposed from the second side of the light emitting element and made of a non-transparent material; removing the carrier to expose the first side of the light emitting element; and forming at least one metal structure at the first side of the light emitting element.

In summary, the package structure is manufactured by wafer-level packaging. Therefore, there is no need for a substrate to carry the light emitting elements as required in the prior art, and the package structure has thickness and width greatly reduced, which satisfies the requirement for miniaturization.

The package structure according to the present disclosure shortens the distance between the fluorescent layer and the light emitting element by allowing the fluorescent layer to combine and be in contact with the second side of the light emitting element, thereby achieving a better luminous efficiency.

Additionally, the side faces of the light emitting element are in contact with and combined with the coating body. As a result, no light will be emitted from the side faces of the light emitting element. Therefore, the heat generated is reduced, and problems such as yellowing of the encapsulant and poor luminous efficiency due to overheating of the fluorescent powder are solved. The metal structure also improves heat dissipation.

### BRIEF DESCRIPTION OF THE DRAWINGS

The present disclosure can be more fully understood by reading the following detailed description of the preferred embodiments, with reference made to the accompanying drawings, wherein:

FIG. 1 is a cross-sectional diagram of a LED package according to the prior art;

FIGS. 2A to 2D are cross-sectional diagrams illustrating a method for manufacturing a package structure in accordance with a first embodiment of the present disclosure, wherein FIG. 2C′ is another embodiment of FIG. 2C;

FIGS. 3A to 3E are cross-sectional diagrams illustrating a method for manufacturing a package structure in accordance with a second embodiment of the present disclosure;

FIG. 4 is a cross-sectional diagram illustrating a package structure in accordance with a third embodiment of the present disclosure; and

FIGS. 5A to 5E are cross-sectional diagrams illustrating a method for manufacturing a package structure in accordance with a fourth embodiment of the present disclosure.

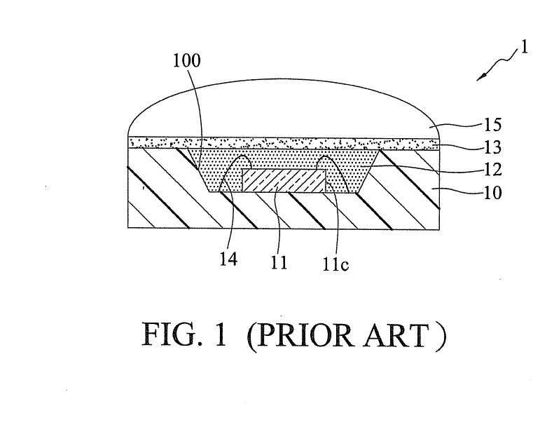

### DETAILED DESCRIPTION OF THE EMBODIMENTS

The present disclosure is described by the following specific embodiments. Those with ordinary skills in the arts can readily understand other advantages and functions of the present disclosure after reading the disclosure of this specification.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the present disclosure, and therefore have no substantial technical meaning. Without affecting the effects created and objectives achieved by the present disclosure, any modifications, changes or adjustments to the structures, ratio relationships or sizes, are to be construed as fall within the range covered by the technical contents disclosed herein. Meanwhile, terms, such as “up”, “down”, “bottom”, “first”, “second”, “a” and the like, are for illustrative purposes only, and are not meant to limit the range implementable by the present disclosure. Any changes or adjustments made to their relative relationships, without modifying the substantial technical contents, are also to be construed as within the range implementable by the present disclosure.

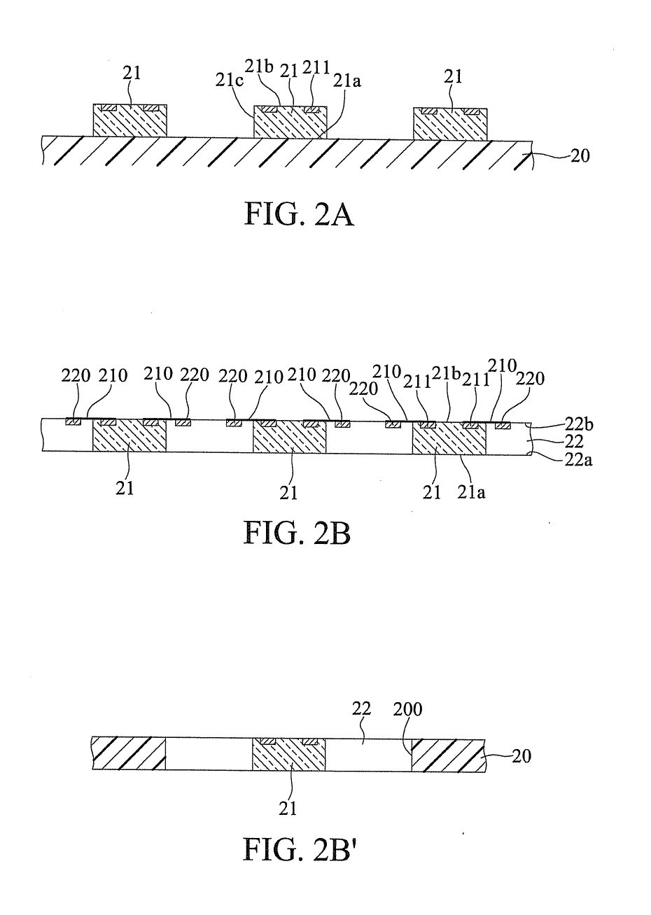

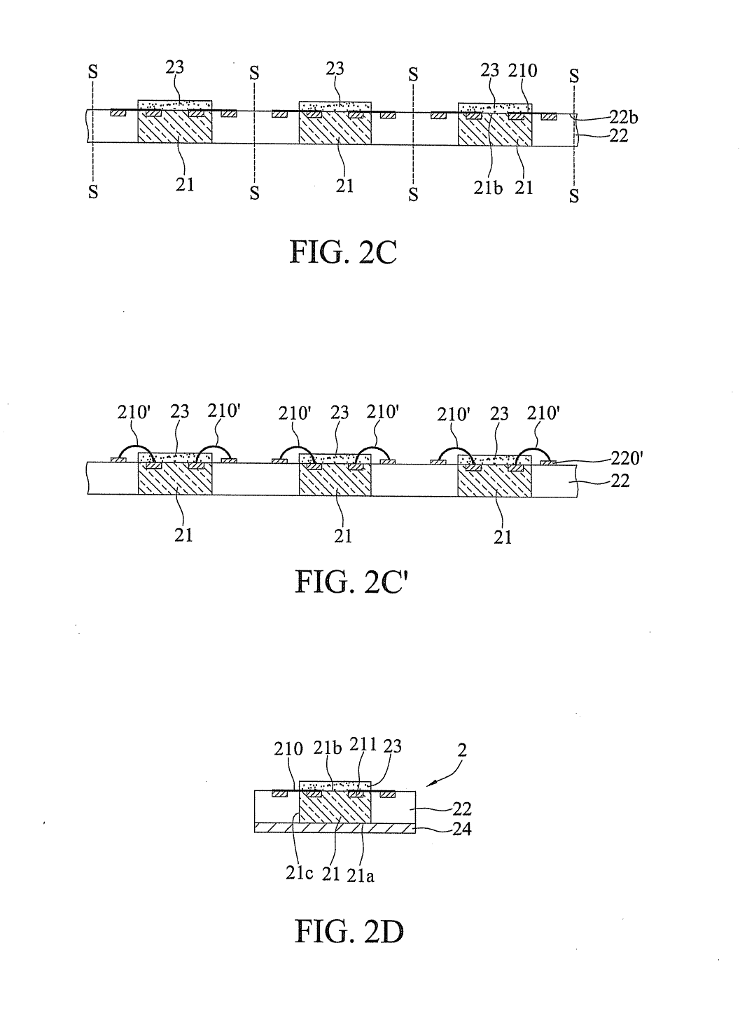

FIGS. 2A to 2D are cross-sectional diagrams illustrating a method for manufacturing a package structure 2 in accordance with a first embodiment of the present disclosure.

As shown in FIG. 2A, a plurality of light emitting elements 21 are combined onto a carrier 20.

In an embodiment, the light emitting elements 21 are LEDs, and each of the LEDs has a first side 21a combined with the carrier 20, a second side 21b opposite to the first side 21a, and side faces 21c adjacent to the first side 21a and the second side 21b. The second side 21b includes a plurality of electrodes 211.

In an embodiment, the second side 21b of the light emitting elements 21 is a light emitting side.

In an embodiment, the carrier 20 can be of various types, and there is no particular constraint on the type of the carrier 20.

As shown in FIG. 2B, a coating body 22 is formed on the carrier 20, and is in contact with and combined with the side faces 21c of the light emitting elements 21. The coating body 22 is exposed from the second side 21b of the light emitting elements 21. Then, the carrier 20 is removed, such that the first side 21a of the light emitting elements 21 is exposed from a first surface 22a of the coating body 22. A plurality of wirings 210 are formed on the second side 21b of the light emitting elements 21.

In an embodiment, the coating body 22 can be made of a non-transparent material such as white glue. The coating body 22 is defined with the first surface 22a combined with the carrier 20 and a second surface 22b opposite to the first surface 22a, such that the second side 21b of the light emitting elements 21 is on the same side as the second surface 22b of the coating body 22.

In an embodiment, the second side 21b of the light emitting elements 21 is flush with the second surface 22b of the coating body 22, such that the second surface 22b of the coating body 22 is exposed from the second side 21b of the light emitting elements 21.

In another embodiment, holes are further formed on the second surface 22b of the coating body 22, to expose the second side 21b of the light emitting elements 21.

In an embodiment, the wirings 210 can be formed by spin coating, and extend onto the second surface 22b of the coating body 22. A plurality of conductive pads 220 are disposed on the second surface 22b of the coating body 22. The wirings 210 are electrically connected to the conductive pads 220 and the electrodes 211.

As shown in FIG. 2C, a fluorescent layer 23 is formed on the second side 21b of the light emitting elements 21 and the second surface 22b of the coating body 22.

In an embodiment, the fluorescent layer 23 coats the wirings 210 on the second side 21b of the light emitting elements 21, and exposes the wirings 210 on the second surface 22b of the coating body 22.

In another embodiment, solder wires 210′ can be used in place of the wirings 210, and external pads 220′ can be used in place of the conductive pads 220, as shown in FIG. 2C′.

In an embodiment, a translucent layer such as glass can also be used to replace the fluorescent layer 23. The glass would be a cover-all layer, and thus covers both the second side 21b of the light emitting elements 21 and the second surface 22b of the coating body 22.

As shown in FIG. 2D, a singulation process is performed along the cutting lines S shown in FIG. 2C. Then, a metal structure 24 is disposed on the first side 21a of each light emitting elements 21 and the first surface 22a of the coating body 22, thereby obtaining a plurality of package structures 2.

In an embodiment, the first side 21a of the light emitting elements 21 is flush with the first surface 22a of the coating body 22, and the metal structure 24 is used as a heat dissipating element.

Moreover, in another embodiment, the metal structure 24 can be formed first, and then singulation is performed.

Therefore, the package structures 2 according to the present disclosure are manufactured by wafer-level packaging, and there is no need for a substrate to carry the light emitting elements 21, as required in the prior art, thus greatly reducing the thickness and width of the package structures 2, satisfying the requirement for miniaturization.

Also, the package structures 2 according to the present disclosure shorten the distance between the fluorescent layer 23 and the light emitting element 21 by allowing the fluorescent layer 23 to combine by contact with the second side 21b of the light emitting element 21, thus achieving a better luminous efficiency.

The side faces 21c of the light emitting element 21 are in contact with and combined with the coating body 22. As a result, no light will be emitted from the side faces 21c of the light emitting element 21. Therefore, the heat generated is reduced, and problems such as yellowing of the encapsulant and poor luminous efficiency due to overheating of the fluorescent powder are solved. The first side 21a of the light emitting element 21 acts as a heat dissipating side, and heat generated by the package structure 2 of the present disclosure is dissipated through the metal structure 24, thus improving heat dissipation.

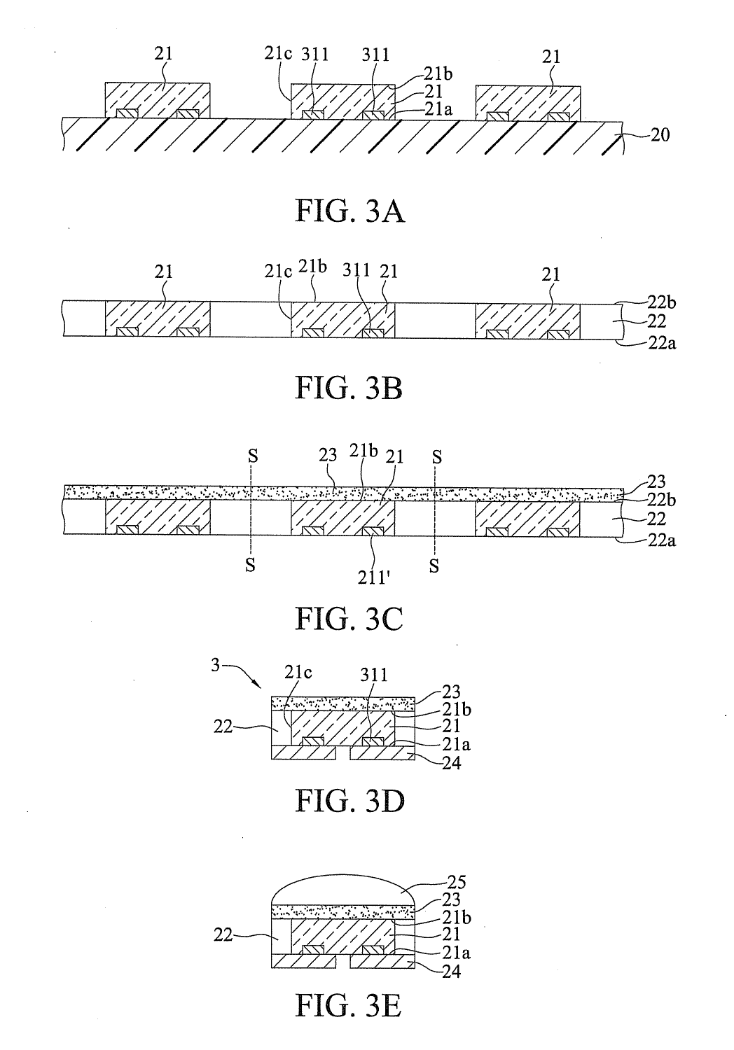

FIGS. 3A to 3E are cross-sectional diagrams illustrating a method for manufacturing a package structure 3 in accordance with a second embodiment of the present disclosure. The second embodiment differs from the first embodiment in locations of the electrodes of the light emitting elements 21.

As shown in FIG. 3A, a plurality of light emitting elements 21 are combined onto a carrier 20, and the first side 21a includes a plurality of electrodes 311.

As shown in FIG. 3B, a coating body 22 is disposed on the carrier 20, such that the coating body 22 coats the side faces 21c of the light emitting elements 21. The second surface 22b of the coating body 22 is exposed from the second side 21b of the light emitting elements 21. Then, the carrier 20 is removed.

As shown in FIG. 3C, a fluorescent layer 23 is formed on the second side 21b of the light emitting elements 21 and the second surface 22b of the coating body 22.

In an embodiment, the fluorescent layer 23 coats the second side 21b of the light emitting elements 21, as well as the whole second surface 22b of the coating body 22.

In another embodiment, the fluorescent layer 23 coats the second side 21b of the light emitting elements 21 and only a portion of the second surface 22b of the coating body 22.

As shown in FIG. 3D, a singulation process is performed along the cutting lines S shown in FIG. 3C, and at least one metal structure 24 is disposed on the first side 21a of the light emitting elements 21 and the first surface 22a of the coating body 22.

In an embodiment, the metal structure 24 is connected with the electrodes 311, and acts as a conductive wire or a heat-dissipating component.

As shown in FIG. 3E, a translucent layer 25 such as a lens is formed on the fluorescent layer 23.

In an embodiment, a subsequent manufacturing step following FIG. 2D may include forming a translucent layer 25 such as a lens on the fluorescent layer 23.

Therefore, the package structures 3 according to the present disclosure are manufactured by wafer-level packaging, and there is no need for a substrate to carry the light emitting elements 21 as required in the prior art, thus greatly reducing the thickness and width of the package structures 3, satisfying the requirement for miniaturization.

The package structures 3 according to the present disclosure shorten the distance between the fluorescent layer 23 and the light emitting element 21 by allowing the fluorescent layer 23 to combine by contact with the second side 21b of the light emitting element 21, thus achieving a better luminous efficiency.

The side faces 21c of the light emitting elements 21 combine by contact with the coating body 22. As a result, no light will be emitted from the side faces 21c of the light emitting elements 21. Therefore, the heat generated is reduced, and problems such as yellowing of the encapsulant and poor luminous efficiency due to overheating of the fluorescent powder are solved. The first side 21a of the light emitting elements 21 acts as a heat dissipating side, and heat generated by the package structure 3 according to the present disclosure is dissipated through the metal structure 24, thus improving heat dissipation.

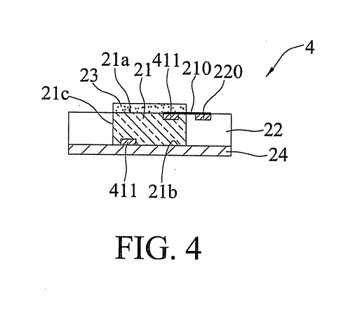

FIG. 4 is a cross-sectional diagram illustrating a package structure 4 in accordance with a third embodiment of the present disclosure. The third embodiment employs the methods for manufacturing the abovementioned embodiments.

As shown in FIG. 4, both the first side 21a and the second side 21b of the light emitting elements 21 include electrodes 411. The wirings 210 electrically connect the conductive pads 220 with the electrodes 411 on the second side 21b, while the metal structure 24 connects by contact the electrodes 411 on the first side 21a.

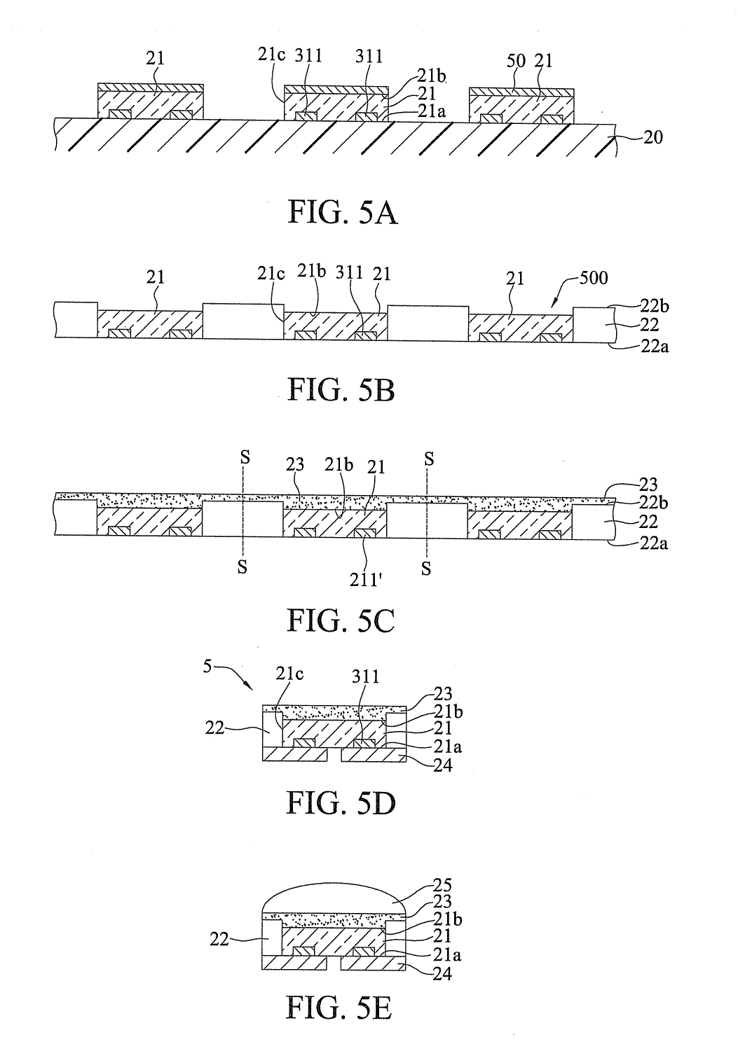

FIGS. 5A to 5E are cross-sectional diagrams illustrating a method for manufacturing a package structure 5 in accordance with a fourth embodiment of the present disclosure. The fourth embodiment differs from the second embodiment in that a thermal release film is further formed in the fourth embodiment.

As shown in FIG. 5A, a plurality of light emitting elements 21 are combined onto a carrier 20, and the second side 21b includes a thermal release film 50.

As shown in FIG. 5B, a coating body 22 is formed on the carrier 20, such that the coating body 22 coats the side face 21c of the light emitting elements 21. The second surface 22b of the coating body 22 exposes the thermal release film 50. Then, the thermal release film 50 and the carrier 20 are removed. There is no limit as to the order in which the thermal release film 50 and the carrier 20 are removed. After the thermal release film 50 is removed, the coating body 22 protrudes from the side face 21c of the light emitting elements 21, higher than the second side 21b of the light emitting elements 21, effectively forming openings 500.

As shown in FIG. 5C, a fluorescent layer 23 is formed in the openings 500 on the second side 21b of the light emitting elements 21 and the second surface 22b of the coating body 22.

In an embodiment, the fluorescent layer 23 coats the second side 21b of the light emitting elements 21, as well as the whole second surface 22b of the coating body 22.

In another embodiment, the fluorescent layer 23 coats the second side 21b of the light emitting element 21 and only a portion of the second surface 22b of the coating body 22.

As shown in FIG. 5D, a singulation process is performed along the cutting lines S shown in FIG. 5C, and at least one metal structure 24 is disposed on the first side 21a of the light emitting elements 21 and the first surface 22a of the coating body 22.

In an embodiment, the metal structure 24 connects by contacts the electrodes 311, and acts as a conductive wire or a heat-dissipating component.

As shown in FIG. 5E, a translucent layer 25 such as a lens is formed on the fluorescent layer 23.

The above embodiments are only used to illustrate the principles of the present disclosure, and should not be construed as to limit the present disclosure in any way. The above embodiments can be modified by those with ordinary skill in the art without departing from the scope of the present disclosure as defined in the following appended claims.

What is claimed is:

1. A package structure, comprising:
at least one light emitting element including opposite first and second sides and side faces adjacent to the first and second sides;
a coating body in contact with and combined with the side faces of the light emitting element, wherein the coating body is made of a non-transparent material; and
at least one metal structure disposed at the first side of the light emitting element.

2. The package structure of claim 1, further comprising a plurality of electrodes disposed on at least one of the first and second sides of the light emitting element.

3. The package structure of claim 2, wherein the metal structure is in contact with and connected to the electrodes on the first side of the light emitting element.

4. The package structure of claim 3, further comprising a plurality of wirings formed on the second side of the light emitting element for electrically connecting the electrodes on the second side of the light emitting element.

5. The package structure of claim 1, wherein the coating body has a surface flush with the first side or the second side of the light emitting element.

6. The package structure of claim 1, wherein the light emitting element is a light emitting diode, the coating body is composed of white glue, and the metal structure is a conductive wire or a heat-dissipating component.

7. The package structure of claim 1, further comprising a fluorescent layer in contact with and combined with the second side of the light emitting element.

8. The package structure of claim 7, further comprising a translucent layer formed on the fluorescent layer.

9. The package structure of claim 1, further comprising a translucent layer in contact with and combined with the second side of the light emitting element.

10. The package structure of claim 1, further comprising a thermal release film formed on the second side of the light emitting element.

11. The package structure of claim 1, wherein the coating body protrudes from the side faces of the light emitting element above the second side of the light emitting element to form an opening.

12. The package structure of claim 11, further comprising a fluorescent layer in contact with and combined with the second side of the light emitting element in the opening.

13. A method for manufacturing a package structure, comprising:
combining on a carrier at least one light emitting element including a first side combined with the carrier, a second side opposite to the first side, and side faces adjacent to the first and second sides;
forming on the carrier a coating body in contact with and combined with the side faces of the light emitting element, wherein the coating body is exposed from the second side of the light emitting element and is made of a non-transparent material;
removing the carrier to expose the first side of the light emitting element; and
disposing at least one metal structure at the first side of the light emitting element.

14. The method of claim 13, wherein the carrier includes a recess for receiving the light emitting element therein, and the coating body is formed in the recess for coating the light emitting element.

15. The method of claim 13, further comprising disposing a plurality of electrodes on at least one of the first and second sides of the light emitting element.

16. The method of claim 15, wherein the metal structure is in contact with and connected to the electrodes on the first side of the light emitting element.

17. The method of claim 15, further comprising forming a plurality of wirings on the second side of the light emitting element for electrically connecting the electrodes on the second side of the light emitting element.

18. The method of claim 13, further comprising combining a fluorescent layer with the second side of the light emitting element.

19. The method of claim 18, further comprising forming a translucent layer on the fluorescent layer.

20. The method of claim 13, further comprising combining a translucent layer with the second side of the light emitting element.

21. The method of claim 13, further comprising performing a singulation process after removing the carrier.

22. The method of claim 13, further comprising disposing a thermal release film on the second side of the light emitting element.

23. The method of claim 22, further comprising removing the thermal release film after forming the coating body.
